(19) United States
(12) Patent Application Publication
(10) Pub. No.: US 2023/0268204 A1
(43) Pub. Date: Aug. 24, 2023

(54) MICRO ELEMENT CARRIER AND MICRO ELEMENT TRANSFER SYSTEM INCLUDING SAME, AND MANUFACTURING METHOD FOR ELECTRONIC PRODUCT IN WHICH MICRO ELEMENT IS MOUNTED

(71) Applicant: POINT ENGINEERING CO., LTD., Chungcheongnam-do (KR)

(72) Inventors: Seung Ho PARK, Gyeonggi-do (KR); Sung Hyun BYUN, Gyeonggi-do (KR); Jeong Hyuk LEE, Gyeonggi-do (KR)

(73) Assignee: POINT ENGINEERING CO., LTD., Chungcheongnam-do (KR)

(21) Appl. No.: 18/020,262

(22) PCT Filed: Aug. 11, 2021
(86) PCT No.: PCT/KR2021/010667

§ 371 Date: Feb. 7, 2023

(30) Foreign Application Priority Data
Aug. 13, 2020 (KR) 10-2020-0101669

(51) Int. Cl. H01L 21/67; H01L 21/683; H01L 25/075; H01L 33/62

(52) U.S. Cl. CPC H01L 21/67144; H01L 21/6835; H01L 25/0753; H01L 33/62; H01L 2221/68354; H01L 2221/68368

(57) ABSTRACT

A microelement transfer system includes a microelement carrier. The microelement carrier includes a first plate, a second plate, and a microelement support. The first plate has a plurality of first through-holes corresponding to respective microelements. The second plate is provided on the first plate and has a second through-hole having a smaller inner diameter than that of the first through-hole. At least one of the first plate and the second plate is made of an anodic oxide film material. The microelement support includes a carrier substrate on which the microelements are temporarily fixed. The microelement transfer system relatively moves at least one of the microelement carrier and the microelement support in at least one direction so that each of the microelements comes into contact with a side wall of a corresponding one of the first through-holes and detaches to be released from the temporarily fixed state.

### TECHNICAL FIELD

The present disclosure relates to a microelement carrier including a transfer head used to transfer microelements, to a microelement transfer system including the same, and a method of manufacturing an electronic product in which the microelements are mounted.

### BACKGROUND ART

While LCD is still the mainstream in the current display market, OLED is rapidly replacing LCD and emerging as the mainstream of the display market. In a situation where display companies are rushing to participate in the OLCED market, micro-LED (hereinafter referred to as “Micro-LED”) displays are emerging as another next-generation display. While the core materials of LCD and OLED are liquid crystal and organic materials, micro-LED displays are displays that use LED chips themselves in units of 1 to 100 micrometers (μm) as light-emitting materials.

In 1999, Cree LED applied for a patent on “a micro-light emitting diode array with improved light extraction” (U.S. Pat. No. 731,673). Since the term “micro-LED” appeared, related research papers have been published one after another, and research has been conducted. As a task to be solved to apply micro-LED to a display, it is necessary to develop a customized microchip based on a flexible material/element for a micro-LED element and technologies for transferring micrometer-sized LED chips, and accurate mounting on display pixel electrodes.

In particular, in relation to the transfer of the micro-LED element to the display substrate, as the size of the LED decreases to the order in a range of 1 to 100 micrometers (μm), conventional pick and place equipment cannot be used, and more high-precision transfer head technology is required.

Therefore, instead of using the existing vacuum suction force, technologies are being developed to use various forces such as electrostatic force, van der Waals force, and magnetic force, and technologies for transferring using materials with variable bonding force due to heat, laser, UV, electromagnetic waves, etc., methods for using rollers, and methods for using fluids have been developed.

Regarding the transfer head technology, several structures have been proposed as described below, but each proposed technology has several disadvantages.

Luxvue Ltd. of the United States proposed a method of transferring micro-LEDs using an electrostatic head (Patent Publication No. 2014-0112486, hereinafter referred to as “preceding disclosure 1”). The transfer principle of the preceding disclosure 1 is the principle of generating adhesion to the micro-LED by an electrification phenomenon by applying a voltage to the head part made of silicon. This method may cause a problem of damage to the micro-LED due to a charging phenomenon caused by a voltage applied to the head when inducing static electricity.

X-Celeprint of the United States proposed a method of transferring micro-LEDs on a wafer to a desired substrate by applying a transfer head made of an elastic polymer material (Patent Publication No. 2017-0019415, hereinafter referred to as “preceding disclosure 2”). Compared to the electrostatic head method, this method does not have a problem with damage to the LED, but the adhesive force of the elastic transfer head must be greater than the adhesive force of the target substrate during the transfer process to stably transfer the micro-LED, and an additional process for electrode formation is required. In addition, it is also a very important factor to continuously maintain the adhesive force of the elastic polymer material.

The Korea Photonics Technology Institute proposed a method of transferring micro-LEDs using a ciliary adhesive structure head (U.S. Pat. No. 1,754,528, hereinafter referred to as “preceding disclosure 3”). However, the preceding disclosure 3 has a disadvantage in that it is difficult to manufacture the adhesive structure of the cilia.

The Korea Institute of Machinery and Materials proposed a method of transferring micro-LEDs by coating an adhesive on a roller (U.S. Pat. No. 1,757,404, hereinafter referred to as “preceding disclosure 4”). However, the preceding disclosure 4 requires continuous use of an adhesive and has the disadvantage in that the micro-LED may be damaged when the roller is pressed.

Samsung Display proposed a method of transferring micro-LEDs to an array substrate by electrostatic induction by applying a negative voltage to the first and second electrodes of the array substrate while the array substrate is immersed in a solution (Patent Application Laid-open Publication No. 10-2017-0026959, hereinafter referred to as “preceding disclosure 5”). However, preceding disclosure 5 has a disadvantage in that a separate solution is required, and a drying process is required in that the micro-LED is immersed in the solution and transferred to the array substrate.

LG Electronics proposed a method of disposing of a head holder between a plurality of pickup heads and a substrate and providing a degree of freedom to the plurality of pickup heads by changing the shape of the head holder by the movement of the plurality of pickup heads (Patent Application Laid-open Publication No. 10-2017-0024906, hereinafter referred to as “preceding disclosure 6”). However, the preceding disclosure 6 has a disadvantage in that a separate process of applying a bonding material to a pickup head is required because it is a method of transferring a micro-LED by applying a bonding material having the adhesive force to the adhesive surfaces of multiple pickup heads.

In order to solve the problems of the preceding disclosures, the above disadvantages must be improved while adopting the basic principles adopted by the preceding disclosures. These disadvantages are derived from the basic principles adopted by the preceding disclosures, so there is a limit to improving them while maintaining the basic principles.

Accordingly, the applicant of the present disclosure does not stop at improving the disadvantages of the related art and proposes a new method that was not considered at all in the preceding disclosures.

### DOCUMENTS OF RELATED ART

### Patent Documents

(Patent Document 1) Korean Patent No. 0731673
(Patent Document 2) Korean Patent Application Laid-open Publication No. 2014-0112486
(Patent Document 3) Korean Patent Application Laid-open Publication No. 2017-0019415
(Patent Document 4) Korean Patent No. 1754528
(Patent Document 5) Korean Patent No. 1757404
(Patent Document 6) Korean Patent Application Laid-open Publication No. 10-2017-0026959
(Patent Document 7) Korean Patent Application Laid-open Publication No. 10-2017-0024906

### DISCLOSURE OF INVENTION

### Technical Problem

Therefore, an objective of the present disclosure is to provide a microelement carrier suitable for efficiently detaching and transferring microelements, such as micro-LEDs or mini-LEDs, from a carrier substrate to a target substrate, a microelement transfer system including the same, and electronic product in which the microelements are mounted.

### Solution to Problem

A microelement carrier, according to one feature of the present disclosure, provides a microelement carrier that adsorbs and transfers microelement by vacuum suction force. The microelement carrier includes: a first plate having a plurality of first through-holes corresponding to respective microelements; and a second plate provided on the upper portion of the first plate having a second through-hole with an inner diameter smaller than that of the first through-hole, in which at least one of the first and second plates is made of an anodic oxide film material.

In addition, it is characterized in that the microelement carrier includes a third plate provided on the upper portion of the second plate and has a cavity chamber connected to the first and second through-holes.

In addition, the microelement carrier includes a porous plate provided on the upper portion of the second plate and made of a porous ceramic material.

Further, the thickness of the first plate in the height direction is smaller than the thickness of the microelement in the height direction.

A microelement transfer system, according to another feature of the present disclosure, includes a first plate having a plurality of first through-holes corresponding to respective microelements and a second plate provided on the upper portion of the first plate having a second through-hole with an inner diameter smaller than that of the first through-hole, in which at least one of the first and second plates includes: a microelement carrier composed of an anodic oxide film material; and a microelement support including a carrier substrate on which the microelements are temporarily fixed, and at least one of the microelement carrier and the microelement support is relatively moved in at least one direction so that the microelement contacts a side wall of the first through-hole to detach a temporarily fixed state of the microelement.

In addition, the carrier substrate includes a glass substrate and a UV adhesive provided on the upper portion of the glass substrate and temporarily fixing the microelement.

In addition, the microelement support includes an adsorption member made of a ceramic material that vacuums the carrier substrate under the carrier substrate.

In addition, at least one direction in which the relative movement is performed is at least one of the x and y directions.

A method for manufacturing an electronic product in which microelements are mounted, according to another aspect of the present disclosure includes: inserting the microelement into the first through-hole of the microelement carrier by moving the microelement carrier toward the carrier substrate; detaching the microelement from a temporarily fixed state by relatively moving at least one of the microelement carrier and the microelement support including the carrier substrate in at least one direction so that the microelement comes into contact with the side wall of the first through-hole; and adsorbing the microelement by vacuum suction force of the microelement carrier.

In addition, the method includes aligning the alignment of microelements with the second through-hole of the microelement carrier prior to adsorbing the microelements.

### Advantageous Effects of Invention

As described above, the microelement carrier, according to the present disclosure, is formed of an anodic oxide film material, so even when the microelement carrier is exposed to a high-temperature environment, thermal deformation due to temperature can be minimized, thereby it is possible to prevent the problem of misalignment for adsorption between microelement and microelement carrier.

In addition, the microelement carrier according to the present disclosure has a space to accommodate each microelement independently, and the microelement is fixed in the space to accommodate the microelement through a hole in which vacuum suction force is formed, thereby preventing damage caused by movement of the microelement during transport.

In addition, by providing a space for accommodating each microelement, there is an effect of preventing static electricity between microelements of a metallic component during adsorption, detachment, and transport of the microelements.

In the microelement transfer system according to the present disclosure, microelement carrier or the microelement support may be relatively moved to detach microelement temporarily fixed to a carrier substrate, through this, when adsorbing for transport and transfer of the micro-elements, collective adsorption to the microelements can be performed more efficiently.

According to the method of manufacturing for the electronic product in which the microelements are mounted according to the present disclosure, since all microelements can be adsorbed collectively without microelements not being adsorbed on the microelement carrier through relatively moving the microelement carrier or microelement support to primarily detach the microelements temporarily fixed on the carrier substrate, and then adsorbing the microelements with a vacuum suction force to detach them from the carrier substrate, the desorption and adsorption efficiency of the microelement is high, and further, the transfer efficiency of the microelement is increased, thereby manufacturing high-quality electronic products.

### BRIEF DESCRIPTION OF DRAWINGS

FIG. 1 is a diagram showing a plurality of micro-LEDs to be transferred by a microelement carrier according to a preferred embodiment of the present disclosure;

FIG. 2 is a diagram showing a micro-LED structure formed by being transferred to a display substrate and mounted by a micro-LED carrier according to a preferred embodiment of this disclosure;

FIG. 3 is a schematic diagram showing a microelement carrier according to a preferred embodiment of the present disclosure and a microelement transfer system according to a preferred embodiment of the present disclosure including the same;

FIG. 4 is a view showing a microelement carrier as viewed from below according to a preferred embodiment of the present disclosure;

FIGS. 5 and 6 are diagrams showing modified examples of the microelement carrier according to the preferred embodiment of the present disclosure; and

FIGS. 7 to 9 are schematic diagrams showing a method of manufacturing an electronic product in which microelements are mounted according to a preferred embodiment of the present disclosure.

### MODE FOR THE INVENTION

The description provided below presents the principles of the disclosure. Therefore, those skilled in the art will be able to implement the principles of the disclosure that are not clearly described or illustrated herein to make various devices that fall within the scope of the present disclosure with reference to the following description. It should be noted that all conditional terms and embodiments recited in this specification are basically intended to help to understand of the concept of the disclosure and are thus not to be construed to limit the disclosure to specific embodiments described herein.

The above objectives, features, and advantages of the present disclosure will become more apparent from the following detailed description taken in conjunction with the accompanying drawings. With reference to the following detailed description and the accompanying drawings, the ordinarily skilled in the art may easily embody the technical concept of the disclosure.

The embodiments described in this specification will be described with reference to cross-sectional views and/or perspective views, which are ideal exemplary diagrams of the present disclosure. The thickness of the membrane and regions shown in the drawings, the diameters of the holes, and the like are exaggerated for an effective description of the technical content. The shapes of the illustrations may vary according to manufacturing techniques and/or tolerances. Also, the number of microelements shown in the drawing is illustratively shown in the drawing only in part. Therefore, the embodiments of the disclosure are not limited to the specific forms illustrated but also include changes in the forms generated according to the manufacturing process.

In describing various embodiments, the same name or the same reference number will be given to components performing the same function even if the embodiment is different. In addition, configurations and operations already described in other embodiments will be omitted for convenience.

Prior to describing preferred embodiments of the present disclosure with reference to the accompanying drawings, a microelement may include a mini-LED or a micro-LED. Here, the micro-LED is not packaged with the molded resin, etc., but is cut from a wafer used for crystal growth and is academically referred to as a size of 1 to 100 μm. However, the microelements described in this specification are not limited to having a size (one side length) of 1 to 100 μm, and include those having a size of 100 μm or more or less than 1 μm.

The microelement carrier, according to a preferred embodiment of the present disclosure, may adsorb microelements using vacuum suction force. In the case of the microelement carrier, there is no limit to the structure as long as it is a structure capable of generating vacuum suction force.

The microelement carrier, according to a preferred embodiment of the present disclosure, may be a carrier substrate that receives microelements from a growth substrate or a temporarily substrate and may be a transfer head that adsorbs microelements positioned on a first substrate, such as a growth substrate, a temporarily substrate, or a carrier substrate and transfers to a second substrate such as a temporarily substrate, a display substrate, or a target substrate. Hereinafter, as an example, it will be described that the microelement carrier, according to a preferred embodiment of the present disclosure, functions as a transfer head that transfers microelements from the first substrate to the second substrate.

The microelement carrier, according to a preferred embodiment of the present disclosure, described below can be applied to microelements including mini-LEDs, micro-LEDs, optical elements, electronic elements, semiconductor chips, and the like. However, hereinafter, a description will be made based on a micro-LED, which is an embodiment of a microelement.

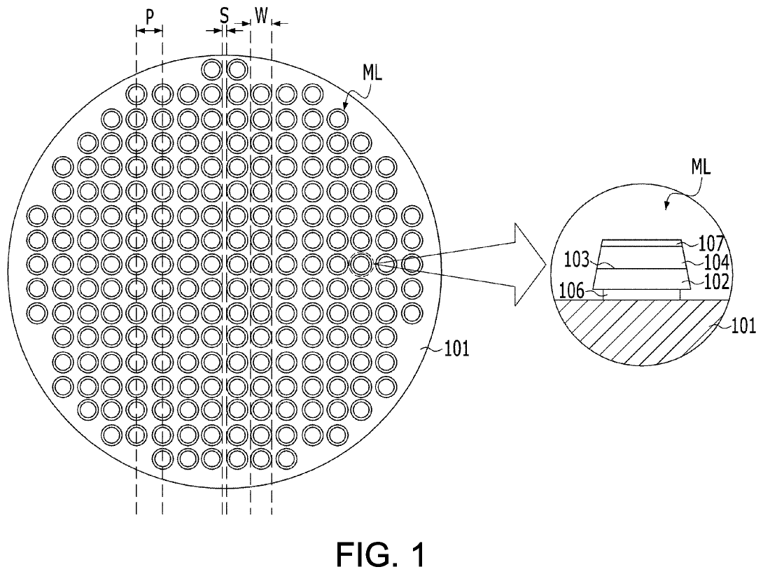

FIG. 1 is a diagram showing a plurality of micro-LED ML to be transferred by a microelement carrier according to a preferred embodiment of the present disclosure. The micro-LED ML is fabricated and positioned on the growth substrate 101.

The growth substrate 101 may be formed of a conductive substrate or an insulating substrate. For example, the growth substrate 101 may be formed of at least one of sapphire, SiC, Si, GaAs, GaN, ZnO, Si, GaP, InP, Ge, and Ga₂O₃.

The micro-LED ML may include a first semiconductor layer 102, a second semiconductor layer 104, an active layer 103 formed between the first semiconductor layer 102 and the second semiconductor layer 104, a first contact electrode 106, and a second contact electrode 107.

The first semiconductor layer 102, the active layer 103, and the second semiconductor layer 104 can be formed using methods such as metal-organic chemical vapor deposition method (MOCVD), chemical vapor deposition method (CVD), plasma-enhanced chemical vapor deposition method (PECVD), molecular beam epitaxy method (MBE), and hydride vapor phase epitaxy (HYPE) method.

The first semiconductor layer 102 may be implemented as, for example, a p-type semiconductor layer. The p-type semiconductor layer may be selected from a semiconductor material having a composition formula of InₓAl_{y}Ga_{1-x-y}N (0≤x≤1, 0≤y≤1, 0≤x+y≤1), for example, GaN, AlN, AlGaN, InGaN, InN, InAlGaN, AlInN, etc., and may be doped with a p-type dopant such as Mg, Zn, Ca, Sr, or Ba.

The second semiconductor layer 104 may include, for example, an n-type semiconductor layer. The n-type semiconductor layer may be selected from a semiconductor material having a composition formula of InₓAl_{y}Ga_{1-x-y}N (0≤x≤1, 0≤y≤1, 0≤x+y≤1), for example, GaN, AlN, AlGaN, InGaN, InN, InAlGaN, AlInN, etc., and an n-type dopant such as Si, Ge, or Sn may be doped.

However, the present disclosure is not limited thereto, and the first semiconductor layer 102 may include an n-type semiconductor layer, and the second semiconductor layer 104 may include a p-type semiconductor layer.

The active layer 103 is a region where electrons and holes are recombined, and as the electrons and holes recombine, the energy level transitions to a lower energy level and light having a corresponding wavelength thereto can be generated. The active layer 103 may include, for example, a semiconductor material having a composition formula of InₓAl_{y}Ga_{1-x-y}N (0≤x≤1, 0≤y≤1, 0≤x+y≤1) and may be formed a single quantum well structure or multiple quantum well structure (MQW). In addition, a quantum wire structure or a quantum dot structure may be included.

A first contact electrode 106 may be formed on the first semiconductor layer 102, and a second contact electrode 107 may be formed on the second semiconductor layer 104. The first contact electrode 106 and/or the second contact electrode 107 may include one or more layers and may be formed of various conductive materials including metals, conductive oxides, and conductive polymers.

A plurality of micro-LEDs ML formed on the growth substrate 101 may be cut using a laser or the like along a cutting line or individually may be separated through an etching process, and a plurality of micro-LEDs ML may be separated from the growth substrate 101 by a laser lift-off process.

In FIG. 1, “P” means the pitch interval between the micro-LEDs ML, “S” means the separation distance between the micro-LEDs ML, and “W” means the width of the micro-LEDs ML. Although FIG. 1 illustrates that the cross-sectional shape of the micro-LED ML is circular, the cross-sectional shape of the micro-LED ML is not limited thereto and may have a cross-sectional shape other than a circular cross-section according to a method manufactured on the growth substrate 101 such as a rectangular cross-section.

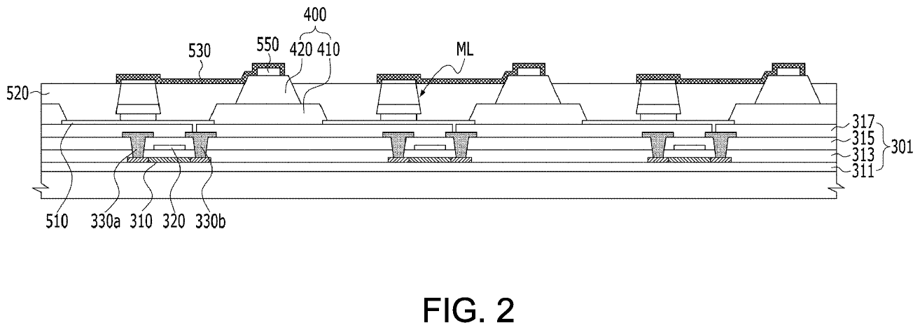

FIG. 2 is a diagram showing a micro-LED structure formed by being transferred to a display substrate and mounted by a micro-LED adsorber according to a preferred embodiment of this disclosure.

The display substrate 301 may include various materials. For example, the display substrate 301 may be made of a transparent glass material containing SiO₂ as a main component. However, the display substrate 301 is not necessarily limited thereto and may be formed of a transparent plastic material and have solubility. Plastic materials may be an organic material selected from the group consisting of insulating organic materials, such as polyether sulfone (PES), polyacrylate (PAR), polyetherimide (PEI), polyethylene naphthalate (PEN), polyethylene terephthalate (PET), polyethylene terephthalate (PET), polyethylene terephthalate (PET), polyphenylene sulfide (PPS), polyarylate, polyimide, polycarbonate (PC), cellulose triacetate (TAC), cellulose acetate propionate (CAP).

When the image is a bottom emission type display implemented in the direction of the display substrate 301, the display substrate 301 should be formed of a transparent material. However, in the case of a top emission type in which an image is implemented in a direction opposite to that of the display substrate 301, the display substrate 301 does not necessarily need to be made of a transparent material. In this case, the display substrate 301 may be formed of metal.

When the display substrate 301 is formed of metal, the display substrate 301 may include at least one selected from the group consisting of iron, chromium, manganese, nickel, titanium, molybdenum, stainless steel (SUS), Invar alloy, Inconel alloy, and Kovar alloy, but is not limited thereto.

The display substrate 301 may include a buffer layer 311. The buffer layer 311 may provide a flat surface and may block the penetration of foreign substances or moisture. For example, the buffer layer 311 may contain an inorganic material such as silicon oxide, silicon nitride, silicon oxynitride, aluminum oxide, aluminum nitride, titanium oxide, or titanium nitride, or an organic material such as polyimide, polyester, or acryl and may be formed of a plurality of laminates among the materials exemplified.

The thin film transistor (TFT) may include an active layer 310, a gate electrode 320, a source electrode 330a, and a drain electrode 330b.

Hereinafter, a case in which the thin film transistor (TFT) is a top gate type in which an active layer 310, a gate electrode 320, a source electrode 330a, and a drain electrode 330b are sequentially formed will be described. However, the present embodiment is not limited thereto, and various types of thin film transistors (TFTs), such as a bottom gate type, may be employed.

The active layer 310 may contain a semiconductor material, for example, amorphous silicon or polycrystalline silicon. However, the present embodiment is not limited thereto, and the active layer 310 may contain various materials. As an optional embodiment, the active layer 310 may contain an organic semiconductor material or the like.

As another alternative embodiment, the active layer 310 may contain an oxide semiconductor material. For example, the active layer 310 may include an oxide of a substance selected from groups 12, 13, and 14 metal elements such as zinc (Zn), indium (In), gallium (Ga), tin (Sn) cadmium (Cd), germanium (Ge), and the like.

A gate insulating layer 313 is formed on the active layer 310. The gate insulating layer 313 serves to insulate the active layer 310 and the gate electrode 320. In the gate insulating layer 313, a film made of an inorganic material such as silicon oxide and/or silicon nitride may be formed as a multilayer or a single layer.

The gate electrode 320 is formed on the upper portion of the gate insulating layer 313. The gate electrode 320 may be connected to a gate line (not shown) for applying an on/off signal to the thin film transistor (TFT).

The gate electrode 320 may be made of a low-resistance metal material. In consideration of adhesion to adjacent layers, surface flatness and processability of the laminated layer, and the like, the gate electrode 320 may be formed of, for example, a single layer or multiple layers of one or more of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), copper (Cu).

An interlayer insulating film 315 is formed on the gate electrode 320. The interlayer insulating film 315 insulates the source electrode 330a and the drain electrode 330b from the gate electrode 320. The interlayer insulating film 315 may be formed of a multi-layer or single-layer film made of an inorganic material. For example, the inorganic material may be a metal oxide or a metal nitride, and specifically, the inorganic material may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZrO₂).

A source electrode 330a and a drain electrode 330b are formed on the interlayer insulating film 315. The source electrode 330a and a drain electrode 330b may be formed of a single layer or multiple layers of one or more of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), copper (Cu). The source electrode 330a and the drain electrode 330b are electrically connected to the source and drain regions of the active layer 310, respectively.

The planarization layer 317 is formed on the thin film transistor (TFT). The planarization layer 317 is formed to cover the thin film transistor (TFT), eliminates the step caused by the thin film transistor (TFT), and flattens the upper surface. The planarization layer 317 may be formed of a single layer or multiple layers of a film made of organic material. Organic materials may include general purpose polymers such as polymethylmethacrylate (PMMA) and polystylene (PS), polymer derivatives having phenolic groups, acrylic polymers, imide-based polymers, arylether-based polymers, amide-based polymers, fluorine-based polymers, p-xylene-based polymers, vinyl alcohol-based polymers, and a blend thereof. Also, the planarization layer 317 may be formed of a composite laminate of an inorganic insulating film and an organic insulating film.

The first electrode 510 is positioned on the planarization layer 317. The first electrode 510 may be electrically connected to the thin film transistor (TFT). Specifically, the first electrode 510 may be electrically connected to the drain electrode 330b through a contact hole formed in the planarization layer 317. The first electrode 510 may have various shapes, for example, may be patterned and formed in an island shape. A bank layer 400 defining a pixel area may be disposed of on the planarization layer 317. The bank layer 400 may include an accommodating concave portion in which the micro-LED ML is accommodated. The bank layer 400 may include, for example, a first bank layer 410 forming an accommodating concave portion. The height of the first bank layer 410 may be determined by the height and viewing angle of the micro-LED ML. The size (width) of the accommodating concave portion may be determined by the resolution and pixel density of the display device. In one embodiment, the height of the micro-LED ML may be greater than the height of the first bank layer 410. The accommodating concave portion may have a rectangular cross-sectional shape, but embodiments of the present disclosure are not limited thereto, and the accommodating concave portion may have various cross-sectional shapes such as polygonal, rectangular, circular, conical, elliptical, and triangular shapes.

The bank layer 400 may further include a second bank layer 420 positioned upper portion of the first bank layer 410. The first bank layer 410 and the second bank layer 420 have a step difference, and the width of the second bank layer 420 may be smaller than that of the first bank layer 410. A conductive layer 550 may be disposed of upper portion of the second bank layer 420. The conductive layer 550 may be disposed in a direction parallel to the data line or the scan line and electrically connected to the second electrode 530. However, the present disclosure is not limited thereto, the second bank layer 420 may be omitted, and the conductive layer 550 may be disposed of upper portion of the first bank layer 410. Alternatively, the second bank layer 420 and the conductive layer 500 may be omitted, and the second electrode 530 may be formed over the entire substrate 301 as a common electrode common to the pixels P. The first bank layer 410 and the second bank layer 420 may include a material that absorbs at least a portion of light, a light reflective material, or a light scattering material. The first bank layer 410 and the second bank layer 420 may include an insulating material that is translucent or opaque to visible light (e.g., light in a wavelength range of 380 nm to 750 nm).

For example, the first bank layer 410 and the second bank layer 420 may include a thermoplastic resin such as polycarbonate (PC), polyethylene terephthalate (PET), polyether sulfone, polyvinyl butyral, polyphenylene ether, polyamide, polyetherimide, norbornene system resin, methacrylic resin, cyclic polyolefin, or a thermosetting resin such as epoxy resin, phenol resin, urethane resin, acrylic resin, vinyl ester resin, imide-based resin, urethane-based resin, urea resin, melamine resin and the like, or an organic insulating material such as polystyrene, polyacrylonitrile, polycarbonate and the like, but is not limited thereto.

As another example, the first bank layer 410 and the second bank layer 420 may be formed of an inorganic insulating material such as an inorganic oxide or inorganic nitride such as SiOₓ, SiNₓ, SiNₓO_{y}, AlOₓ, TiOₓ, TaOₓ, or ZnOₓ, but is not limited thereto. In one embodiment, the first bank layer 410 and the second bank layer 420 may be formed of an opaque material such as a black matrix material. Insulative black matrix materials include resins or paste containing organic resins, glass paste, and black pigments, or metal particles such as nickel, aluminum, molybdenum and alloys thereof, metal oxide particles (e.g., chromium oxide), or metal nitride particles (e.g., chromium nitride) and the like. In a modified example, the first bank layer 410 and the second bank layer 420 may be a mirror reflector formed of a distributed Bragg reflector (DBR) having high reflectivity or metal.

A micro-LED ML is disposed in the accommodating concave portion. The micro-LED ML may be electrically connected to the first electrode 510 in the accommodating concave portion.

The micro-LED ML emits light having wavelengths such as red, green, blue, and white, and white light can be implemented by using a fluorescent material or combining colors. The micro-LEDs (MLs) may be accommodated in the accommodating concave portion of the display substrate 301 by individually or in plural pieces being picked up on the growth substrate 101 by the transfer head according to the embodiment of the present disclosure and transferred to the display substrate 301.

The micro-LED ML includes a p-n diode, a first contact electrode 106 disposed on one side of the p-n diode, and a second contact electrode 107 disposed on the opposite side of the first contact electrode 106. The first contact electrode 106 may be connected to the first electrode 510, and the second contact electrode 107 may be connected to the second electrode 530.

The first electrode 510 may include a reflective film formed of Ag, Mg, Al, Pt, Pd, Au, Ni, Nd, Ir, Cr, and compounds thereof and a transparent or translucent electrode layer formed on the reflective film. The transparent or translucent electrode layer may include at least one selected from the group consisting of indium tin oxide (ITO), indium zinc oxide (IZO), zinc oxide (ZnO), indium oxide (In₂O₃), and indium gallium oxide (IGO), and aluminum zinc oxide (AZO).

The passivation layer 520 surrounds the micro-LED ML in the accommodating concave portion. The passivation layer 520 covers the accommodating concave portion and the first electrode 510 by filling the space between the bank layer 400 and the micro-LED ML. The passivation layer 520 may be formed of organic insulating material. For example, the passivation layer 520 may be formed of acryl, polymethyl methacrylate (PMMA), benzocyclobutene (BCB), polyimide, acrylate, epoxy, and polyester, etc., but is limited thereto.

The passivation layer 520 is formed with a height not covering the top of the micro-LED ML, for example, the second contact electrode 107 so that the second contact electrode 107 is exposed. A second electrode 530 electrically connected to the exposed second contact electrode 107 of the micro-LED ML may be formed on the passivation layer 520.

The second electrode 530 may be disposed of on the micro-LED ML and the passivation layer 520. The second electrode 530 may be formed of a transparent conductive material such as ITO, IZO, ZnO, or In₂O₃.

In the above description, the vertical micro-LED ML in which the first and second contact electrodes 106 and 107 are respectively provided on the upper and lower surfaces of the micro-LED ML has been described as an example, but a preferred embodiment of the present disclosure may be a flip type or lateral type micro-LED ML in which the first and second contact electrodes 106 and 107 are provided on either upper or lower surface of the micro-LED ML, and in this case, the first and second electrodes 510 and 530 may also be appropriately provided.

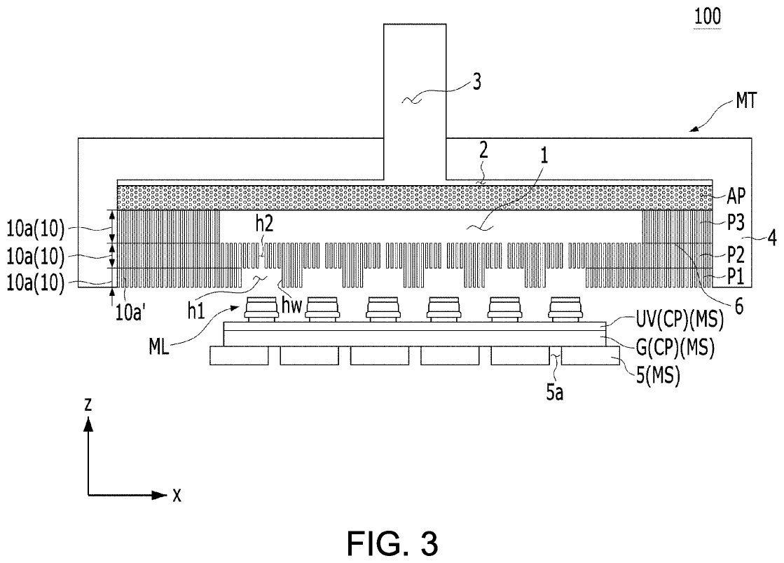

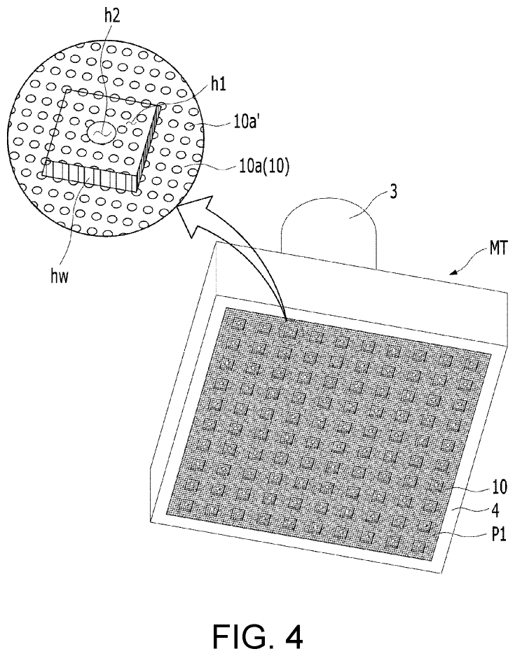

FIG. 3 is a schematic diagram showing a microelement carrier according to a preferred embodiment of the present disclosure and a microelement transfer system 100 according to a preferred embodiment of the present disclosure including the same, and FIG. 4 is a view showing the microelement carrier MT according to a preferred embodiment of the present disclosure as viewed from below. However, for easy description, FIG. 3 shows that the number of microelements ML on the carrier substrate (CP) is enlarged and exaggerated as an example, so that the number is six. Accordingly, the first and second through-holes h1 and h2 of the microelement carrier MT are also shown, corresponding to the number of microelements ML.

As shown in FIG. 3, a preferred microelement carrier MT of the present disclosure includes a first plate P1 having a plurality of first through-holes h1 corresponding to each microelement ML and a second plate P2 provided on the upper portion of the first plate P1 and having a second through-hole h2 having a smaller inner diameter than the first through-hole h1, and at least one of the first and second plates P1 and P2 may be made of the anodic oxide film 10 material.

In the microelement carrier MT according to a preferred embodiment of the present disclosure, only the first plate P1 may be made of the anodic oxide film 10 material, and only the second plate P2 may be made of the anodic oxide film 10 material, and both the first and second plates P1 and P2 may be made of the anodic oxide film 10 material. As shown in FIG. 1, in the microelement carrier MT according to a preferred embodiment of the present disclosure, for example, both the first and second plates P1 and P2 may be made of an anodic oxide film 10 material. The anodic oxide film 10 means a film formed by anodic oxidation of a base metal, and the pore hole 10a′ means a hole formed in the process of forming the anodic oxide film 10 by anodic oxidation of a metal. For example, when the base material is aluminum (Al) or an aluminum alloy, when the base material is anodized, an anodized film made of aluminum oxide (Al₂O₃) is formed on the surface of the base material. The anodic oxide film 10 formed as described above is vertically divided into a barrier layer 10b without pore holes 10a′ formed therein and a porous layer 10a with pore holes 10a′ formed therein. The barrier layer 10b is positioned on an upper portion of the base material, and the porous layer 10a is positioned on an upper portion of barrier layer 10b. In this way, when the base material is removed from the base material on which the anodic oxide film 10 having the barrier layer 10b and the porous layer 10a is formed, only the anodic oxide film 10 made of aluminum oxide (Al₂O₃) remains.

The anodic oxidation film 10 may be formed in a structure in which the barrier layer 10b formed during anodic oxidation is removed to pass through the upper and lower pores 10a′. Alternatively, the barrier layer 10b formed during anodization may remain as it is and form a structure to seal one end of the top and bottom of the pore hole 10a′.

The anodic oxide film 10 has a thermal expansion coefficient of 2 to 3 ppm/° C. Due to this, when exposed to a high-temperature environment, thermal deformation caused by temperature may be small. For example, the microelement carrier MT, according to a preferred embodiment of the present disclosure, can be used in a field that performs a process in a high-temperature environment, such as a semiconductor field or a display field. At this time, at least one of the first and second plates, P1 and P2, constituting the microelement carrier MT according to the preferred embodiment of the present disclosure is made of the anodic oxide film 10 material, thereby minimizing the thermal deformation of the product. As a result, when the microelement carrier MT according to a preferred embodiment of the present disclosure adsorbs the microelements ML for transport, the problem of misalignment with the microelement ML may be prevented.

A third plate P3 may be provided on the second plate P2. The third plate P3 may have a cavity chamber 1 connecting with the first and second through-holes h1 and h2. The third plate P3 may be configured to an anodic oxide film 10, constituting at least one of the first and second plates P1 and P2. Alternatively, the third plate P3 may be configured to a porous material having vertical pores or random pores. However, preferably, the third plate P3 may be configured to the anodic oxide film 10 material constituting at least one of the first and second plates P1 and P2. This is to prevent the alignment with the microelement ML from being distorted during the adsorption process of the microelement ML by minimizing thermal deformation due to temperature when the microelement carrier MT according to a preferred embodiment of the present disclosure is exposed to a high-temperature environment.

The cavity chamber 1 may be formed on the third plate P3 by wet etching.

A porous plate AP may be provided on the third plate P3. The porous ceramic material constituting the porous plate AP may be formed of a sintered body of a porous ceramic material in which pores are randomly arranged.

The porous plate AP may perform a function of supporting the first to third plates P1, P2, and P3 on an upper portion of the third plate P3. Therefore, the porous plate AP may be formed of a porous support having arbitrary pores, and the material is not limited as long as it may achieve a function of supporting plates including the first to third plates P1, P2, and P3. The porous plate AP may be formed of a hard porous support having an effect of preventing central sagging phenomenon of the plate. As an example, a sintered body of a porous ceramic material constituting the porous plate AP may be one material constituting the hard porous support. At least one of the first plate P1 and the second plate P2 may be made of the anodic oxide film 10 material. In the case of the anodic oxide film 10 material, the anodic oxide film material may be provided in the form of a thin film. Therefore, when the microelement carrier MT according to the preferred embodiment of this disclosure includes a porous plate (AP), the microelement carrier MT may perform a function of preventing the plate made of the anode oxide film 10 from being deformed.

In addition, the porous plate AP may be composed of a porous buffer for buffering contact between the first plate P1 directly contacting the microelement ML. The material of the porous plate AP is not limited as long as the material can achieve a function of buffering the first plate P1. The porous plate AP may be formed of a soft porous buffer that helps prevent the first plate from contacting the microelement ML to damage the microelement ML when the first plate P1 contacts the microelement ML and adsorbs the microelement ML by a vacuum suction force formed in the second through-hole h2 of the second plate P2. For example, the porous plate AP may be a porous elastic material such as a sponge.

A support part 4 may be provided around (upper portion and/or side portion) of the porous plate AP. The support part 4 may support the porous plate AP. Also, the support part 4 may support at least one of the first to third plates P1, P2, and P3.

A vacuum chamber 2 may be provided in the support part 4. The vacuum chamber 2 may be connected to a vacuum port that supplies or releases air pressure. A porous plate AP may be present between the vacuum chamber 2 and the cavity chamber 1. The porous plate AP can diffuse and distribute the air pressure supplied through the suction pipe 3 within the cavity chamber 1 according to the operation of the vacuum port.

The air pressure supplied to the vacuum chamber 2 may be transferred to the upper portion of the porous plate AP. As shown in FIG. 3, the vacuum chamber 2 may be connected to the entire upper surface of the porous plate AP. In addition, the vacuum chamber 2 may be connected over at least a portion of the upper surface of the porous plate AP. The porous plate AP may be spaced apart from the support part 4 by a predetermined distance. A vacuum chamber 2 may be formed by the spaced distance. Accordingly, the air pressure supplied to the vacuum chamber 2 may be uniformly transferred to the upper surface of the porous plate AP. The air pressure transferred to the porous plate AP may be uniformized by irregular pores formed in the porous plate AP. The uniformized air pressure may be transferred to the cavity chamber 1 of the third plate P3 provided under the porous plate AP.

The air pressure transferred to the cavity chamber 1 may be transferred to the second through-hole h2 connecting to the cavity chamber 1. As a result, a vacuum suction force capable of adsorbing the microelement ML is formed in the second through-hole h2, thereby adsorbing the microelement ML. The air pressure transferred to the cavity chamber 1 may also be transferred to the pore hole 10a′ existing around the second through-hole h2. Since the pore hole 10a′ is formed in a fine size, a fine vacuum suction force may be formed through the air pressure transferred to the pore hole 10a′. After the microelement ML is adsorbed by the vacuum suction force formed in the second through-hole h2, the vacuum suction force formed through the pore hole 10a′ may assist the stable adsorption of the microelement ML through the second through-hole h2. In detail, referring to the enlarged portion ‘A’ of FIG. 4, the second through-hole h2 may be formed to have an inner diameter larger than the inner diameter of the pore hole 10a′. Accordingly, the vacuum suction force generated through the air pressure transferred to the second through-hole h2 may be sufficient to adsorb the microelement ML than the vacuum suction force generated through the air pressure transferred through the pore hole 10a′. When the microelement ML is adsorbed by the vacuum suction force of the second through-hole h2, the vacuum suction force formed in the pore hole 10a′ present around the second through-hole h2 may assist in adsorbing the outer part of the microelement ML. Through this, adsorption of the microelement ML through the second through-hole h2 can be more effectively achieved. As a result, during the transfer process of the microelement ML using the microelement carrier MT according to the preferred embodiment of the present disclosure, the microelement ML can be efficiently transferred without the problem of being detached.

As shown in FIG. 3, the microelement carrier MT, according to a preferred embodiment of the present disclosure, may be laminated in the order of a first plate P1, a second plate P2, a third plate P3, and a porous plate AP, and may be laminated in the order of a porous plate AP provided on the first plate P1, the second plate P2, and the second plate P2.

The microelement carrier MT may include, as an example, the first plate P1, the second plate P2, the third plate P3, and the porous plate AP may be laminated in order, but the microelement carrier MT according to a preferred embodiment of this disclosure may be laminated in order by including only the first and second plates P1, P2. In this case, the upper surface of the second plate P2 may be maintained spaced apart from the support part 4 by a certain distance so that the upper surface of the second plate P2 may connect to the vacuum chamber 2. Accordingly, air pressure transferred through the vacuum chamber 2 may be transferred to the second through-hole h2 of the second plate P2 to form a vacuum suction force in the second through-hole h2.

In addition, the microelement carrier MT, according to a preferred embodiment of the present disclosure, may be composed of two plates including a first plate P1 and a second plate P2, and may also be composed of four plates including the first plate to third plate P1, P2, P3, and the porous plate AP. However, the number of plates constituting the microelement carrier MT according to a preferred embodiment of the present disclosure is not limited thereto, and the microelement carrier MT according to a preferred embodiment of the present disclosure includes at least one plate, preferably, may include at least one plates made of the anodic oxide film 10 material.

The first plate P1, the second plate P2, the third plate P3, and the porous plate AP may be bonded and integrated by the bonding layer 6 provided at their interfaces. The bonding layer 6 may be a photosensitive material, for example, may be a dry film photoresist (DFR).

Meanwhile, the bonding layer 6 may be a thermosetting resin. In this case, the thermosetting resin material may be a polyimide resin, a polyquinoline resin, a polyamidimide resin, an epoxy resin, a polyphenylene ether resin, and a fluoro resin.

The microelement carrier MT, according to a preferred embodiment of the present disclosure, may have a structure in which the first through-hole h1 of the first plate P1, the second through-hole h2 of the second plate P2, and the cavity chamber 1 of the third plate P3 connect to each other in accordance with a structure in which the first plate P1, the second plate P2, the third plate P3, and the porous plate AP are sequentially laminated.

The first through-hole h1 of the first plate P1 may be formed to pass through the first plate P1 in the thickness direction. A plurality of first through-holes h1 may be provided to correspond to the microelement ML. The first through-hole h1 may be formed using wet etching when the first plate P1 is made of the anodic oxide film 10 material. The first through-hole h1 may have a size larger than that of the microelement ML. As a result, microelement ML may be inserted into the first through-hole h1. Accordingly, the first through-hole h1 may function as a seating groove in which the microelement ML is inserted and seated therein. In addition, since the first through-hole h1 is provided in plurality to correspond to each microelement ML, each microelement ML can be accommodated in the first through-hole h1 and separated individually.

The microelement carrier MT, according to a preferred embodiment of the present disclosure, may prevent static electricity from occurring between the microelement ML by separating the microelement ML individually through the first through-hole h1 corresponding to each microelement ML.

In addition, when the microelement ML is detached from the carrier substrate CP on which the microelement ML is temporarily fixed, the microelement ML can be detached more efficiently. In detail, the internal microelement ML are pushed to move a certain distance through the sidewall hw of the first through-hole h1 in the first through-hole h1 in which each microelement ML is individually accommodated. Through this, a primary detaching process through position movement is performed prior to completely detaching the microelement ML in a temporarily fixed state from the carrier substrate CP so that the detaching process of the microelement ML can be performed more effectively.

The microelement carrier MT, according to a preferred embodiment of the present disclosure, forms a structure in which the microelement ML is inserted into the first through-hole h1 so that the microelement ML can be prevented from being separated while the microelement ML is transferred. In addition, when the microelement carrier MT, according to a preferred embodiment of the present disclosure, is moved for the next process, the arrangement of the microelement ML may be prevented from being disturbed by limiting the moving range of the microelement ML through the first through-hole h1. The microelement ML inserted into the first through-hole h1 is fixed inside the first through-hole h1 by the vacuum suction force formed in the second through-hole h2 corresponding to the first through-hole h1. Accordingly, damage due to the movement of the microelement ML in the first through-hole h1 may be prevented.

The thickness of the first through-hole h1 in the height direction may be smaller than the thickness of the microelement ML in the height direction. This may be to maintain a relatively small separation distance between the upper surface of the microelement ML inserted into the first through-hole h1 and the lower opening of the second through-hole h2 provided in the section positioned at the lower portion of the second through-hole h2 in the drawing of FIG. 3. For example, when the thickness of the first through-hole h1 in the height direction is greater than the thickness of the microelement ML in the height direction, the separation distance between the upper surface of the microelement ML inserted into the first through-hole h1 and the corresponding lower opening of the second through-hole h2 may be maintained large. When the separation distance between the lower opening of the second through-hole h2 and the upper surface of the microelement ML is large, compared to a case in which a separation distance between a lower opening of the second through-hole h2 and an upper surface of the microelement ML is relatively small, it may be difficult to adsorb the microelement ML by a vacuum suction force formed in the second through-hole h2. This may cause a problem of lowering the overall microelement ML adsorption rate of the microelement carrier that adsorbs the microelement ML.

However, the microelement carrier MT, according to a preferred embodiment of the present disclosure, includes a first plate P1 having a thickness in the height direction smaller than the thickness of the microelement ML in the height direction so that the first through-hole h1 having a thickness in the height direction smaller than the thickness of the microelement ML in the height direction may be provided. Therefore, the microelement carrier MT according to a preferred embodiment of the present disclosure may have a relatively small separation distance between the upper surface of the microelement ML inserted into the first through-hole h1 and the lower opening of the second through-hole h2 corresponding to the microelement ML, and thus may be in a state sufficient to adsorb the microelement ML with a vacuum suction force formed in the second through-hole h2. As a result, when the microelement ML is collectively adsorbed, the microelement carrier MT according to a preferred embodiment of the present disclosure may effectively adsorb the entire microelement ML without the microelement ML being insufficiently attached to the second through-hole h2 corresponding to each microelement ML.

The second plate P2 may include a plurality of second through-holes h2 passing through the second plate P2 in the thickness direction. The second through-hole h2 may be formed using wet etching when the second plate P2 is made of the anodic oxide film 10 material.

The third plate P3 may include a cavity chamber 1 passing through the third plate P3 in a thickness direction. At this time, in the cavity chamber 1, the vertical projection area of the first through-hole h1 of the first plate P1 and the second through-hole h2 of the second plate P2 with respect to the third plate P3 may be provided to be located inside a cavity chamber 1. As a result, a structure is formed in which the first and second through-holes h1 and h2 are connected to the cavity chamber 1, so that the air pressure transferred to the cavity chamber 1 is transferred to the first and second through-holes h1 and h2. Although only one cavity chamber 1 is shown in the drawing of FIG. 3, a plurality of cavity chamber 1 may be formed. When a plurality of cavity chambers 1 is formed, a plurality of second through-holes h2 may be connected to each of the cavity chambers 1. In addition, a first through-hole h1 corresponding to a plurality of second through-holes h2 may be connected to each other.

As shown in FIG. 4, a plurality of first through-holes h1 may be formed in the first plate P1. The arrangement of the first through-holes h1 may be determined in consideration of the arrangement of the microelement ML to be transferred. For example, the first through-hole h1 may have a rectangular horizontal cross-sectional shape. Alternatively, the first through-hole h1 may have a circular horizontal cross-sectional shape. The shape of the horizontal cross-section of the first through-hole h1 is not limited thereto and may be formed in other cross-sectional shapes. The first through-hole h1 may have a side wall hw as the first through-hole passes through the first plate P1 in the thickness direction. The side wall hw may be a contact surface in contact with the microelement ML according to the moving direction of the microelement carrier MT when the microelement ML is inserted into the first through-hole h1 and then the microelement carrier MT moves in at least one of x and y directions. The microelement ML may be primarily detached while moving a certain distance in a temporarily fixed state on the carrier substrate CP by contact with the side wall hw.

A plurality of second through-holes h2 corresponding to each of the plurality of first through-holes h1 may be formed in the second plate P2. Accordingly, at least one second through-hole h2 may be connected to the first through-hole h1. As shown in FIG. 4, as an example, the second through-hole h2 may have a circular horizontal cross-sectional shape. Alternatively, the second through-hole h2 may have a rectangular horizontal cross-sectional shape. The shape of the second through-hole h2 is not limited thereto and may be formed in other cross-sectional shapes.

As shown in FIG. 4, at least a portion of one surface of the second plate P2 may be exposed to the outside through the first through-hole h1 to form a seating groove in which the microelement ML is seated. When the microelement ML is inserted into the first through-hole h1, a lower surface of the microelement ML may come into contact with at least a portion of one surface of the second plate P2. When the second plate P2 is provided with the anodic oxide film 10 composed only of the porous layer 10a, at least a portion of one surface of the second plate P2 exposed to the outside may be a porous layer 10a. In contrast, when the second plate P2 is provided with a barrier layer 10b and an anodic oxide film 10 including a porous layer 10a provided on the barrier layer 10b, at least a portion of one surface of the second plate P2 exposed to the outside may be a barrier layer 10b.

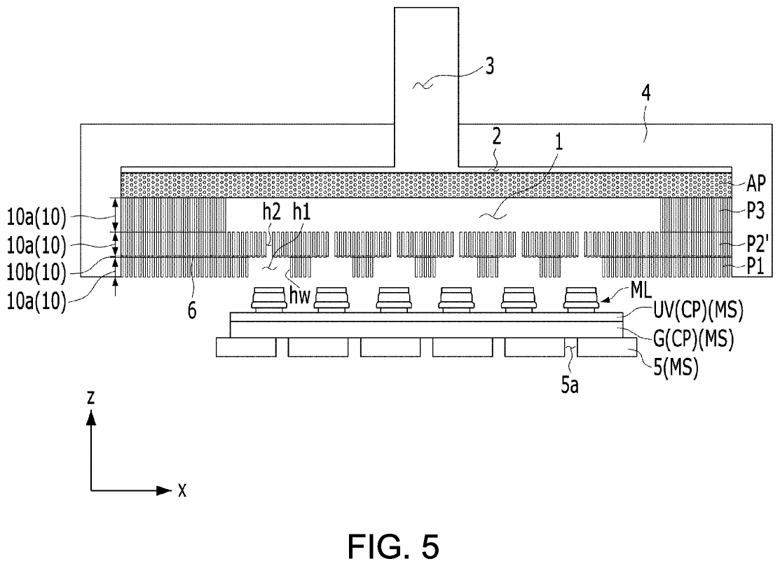

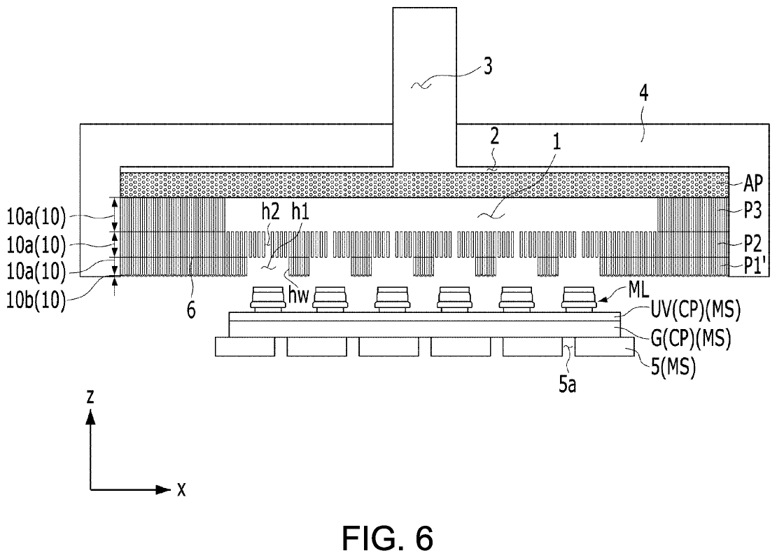

FIGS. 5 and 6 are diagrams showing modified examples of the microelement carrier MT according to the preferred embodiment of the present disclosure.

FIG. 5 is a diagram showing a first modified example of the microelement carrier MT according to a preferred embodiment of the present disclosure. In the first modified example, the second plate P2 is formed of the anodic oxide film 10 material including the barrier layer 10b and the porous layer 10a, and the first plate P1 is formed of only the porous layer 10a, and the microelement carrier MT may be laminated in the order of the first plate P1, the second plate P2′, the third plate P3, and the porous plate AP. In other words, the first modified example is different from the microelement carrier MT according to a preferred embodiment of the present disclosure in which the second plate P2′ is formed of a cathode oxide film 10 material including a barrier layer 10b and a porous layer 10a.

As shown in FIG. 5, in the first modified example, at least a portion of one surface of the second plate P2′ exposed to the outside through the first through-hole h1 may be a barrier layer 10b. In the first modified example, when the microelement ML is adsorbed through the vacuum suction force of the second through-hole h2, the vicinity of the lower opening of the second through-hole h2 in direct contact with an upper surface of the microelement ML may be formed as a barrier layer 10b. In other words, the remaining area of the horizontal area of the upper surface of the microelement ML, except for the horizontal area of the lower opening of the second through-hole h2 may be contacted at least a portion of the barrier layer 10b of one surface of the second plate P2′ exposed to the outside. When the surface directly contacting the upper surface of the microelement ML is the barrier layer 10b, when the microelement ML is adsorbed using the first modified example, there is an advantage in that scratches that may occur due to contact with the pore hole 10′ on the upper surface of the microelement ML can be prevented.

FIG. 6 is a diagram showing a second modified example of the microelement carrier MT according to a preferred embodiment of the present disclosure. In other words, the second modified example is different from the microelement carrier MT according to a preferred embodiment of the present disclosure in which the first plate P1′ is formed of a barrier layer 10b and an anodic oxide film 10 material having a porous layer 10a on upper portion of the barrier layer 10b.

As shown in FIG. 6, in the second modified example, the first plate P1′ is formed of an anodic oxide film 10 material including a barrier layer 10b and a porous layer 10a, and the second plates P2 may be formed of the anodic oxide film 10 material composed only of the porous layer 10a.

One surface of the first plate P1′ may be a surface exposed to the outside. As an example, one surface of the first plate P1′ may be the lower surface of the first plate P1′ in the drawing of FIG. 6. The remaining area of the entire area of the lower surface of the first plate P1′ except for the area in which each of the first through-holes h1 is formed, may be exposed to the outside. For example, the first plate P1′ may form a lowermost portion of the product, and thus one surface of the first plate P1′ may form a lower surface of the product. In other words, the lower surface of the first plate P1′ exposed to the outside may form the lower surface of the product. In the second modified example, the lower surface thereof may be configured as a barrier layer 10b by including a first plate P1′ made of the anodic oxide film 10 material including the barrier layer 10b and the porous layer 10a. The barrier layer 10b may have a lower surface of the product formed in a shielding structure. Accordingly, in the process of adsorbing the microelement ML, a problem in which fine particles generated in the pore holes 10a′ constituting the inside of the product fall off toward the microelement ML can be prevented. Alternatively, fine particles present in the transfer space may be attached to the inside of the pore hole 10a′ to prevent the transfer of the microelement ML from being disturbed.

The microelement carrier MT, according to a preferred embodiment of the present disclosure, is formed of at least one of the first and second plates P1 and P2 made of the anodic oxide film 10 material, and thus thermal deformation due to temperature may be minimized when exposed to a high-temperature environment. Accordingly, even when the microelement carrier MT, according to a preferred embodiment of the present disclosure, is exposed to a high-temperature environment, a problem in which the position of the second through-hole h2 where the vacuum suction force for adsorbing the microelement ML is formed is deformed by temperature can be minimized. As a result, when the microelement ML are adsorbed using the microelement carrier MT according to a preferred embodiment of the present disclosure, the problem of misalignment between the second through-hole h2 and the microelement ML for adsorption can be prevented, and adsorption efficiency can be improved.

In detail, in the process of collectively adsorbing and transferring the microelement ML, when the microelement carrier performing the function of transferring the microelement ML is thermally deformed by a high temperature, the positional arrangement of the suction holes where the vacuum suction force for adsorbing the microelement ML is formed may be modified. When the positional arrangement of the adsorption holes is modified, the alignment for adsorption between the microelement ML corresponding to each adsorption hole and the adsorption hole may be distorted, and thus the adsorption efficiency may decrease. However, the microelement carrier MT, according to a preferred embodiment of the present disclosure, is composed of an anodic oxide film 10 material capable of minimizing thermal deformation due to a high temperature, and can prevent a problem of misalignment for adsorption between the second through-hole h2 functioning as an adsorption hole and the microelement ML. In addition, the insertion position between the first through-hole h1 and the microelement ML provided for efficient detachment and transfer of the microelement ML may be prevented.

In addition, the microelement carrier MT, according to a preferred embodiment of the present disclosure, may allow the microelement ML inserted into the first through-hole h1 to be fixed inside the first through-hole h1 by a vacuum suction force formed in the second through-hole h2 corresponding to the first through-hole h1. Accordingly, damage due to movement of the microelement ML in the first through-hole h1 may be prevented.

The microelement to be transported by the microelement carrier MT according to a preferred embodiment of the present disclosure generally have a size of 100 μm or less, and the number of microelements to be transferred at once can range from hundreds of thousands to hundreds of thousands. Therefore, in order to transfer these microelements at once, tens of thousands to hundreds of thousands of adsorption holes for adsorbing the microelements and seating grooves corresponding to the adsorption holes to seat the microelements are required with a size of about 100 μm. When the adsorption hole and the seating groove are processed one by one to the size of the microelement, the processing is difficult due to the small size, and the processing cost may increase depending on the difficulty of the processing. In addition, since the corner portions of the seating grooves are rounded according to the processing means, it may be difficult to form a gap between the seating grooves at fine pitch intervals. However, the microelement carrier MT, according to a preferred embodiment of the present disclosure, is formed of the anodic oxide film 10 material, and may collectively form a second through-hole h2 functioning as an adsorption hole and a first through-hole h1 functioning as a seating groove using wet etching. As a result, it is possible to reduce the manufacturing cost required to form the suction hole and the seating groove, and since there is no restriction on the horizontal cross-sectional shape of the first and second through-holes h1, h2, it may be easy to form a fine pitch gap between the first through-holes h1 functioning as a seating groove.

The microelement transfer system 100, according to a preferred embodiment of the present disclosure, includes the microelement carrier MT according to a preferred embodiment of the present disclosure, so that the microelement ML of the carrier substrate CP may be effectively transferred to the target substrate.

FIG. 3 shows a state before the process of detaching the temporarily fixed state of the microelement ML is performed.

As shown in FIG. 3, the microelement transfer system 100, according to a preferred embodiment of the present disclosure, includes a microelement carrier MT including a first plate P1 having a plurality of first through-holes h1 corresponding to each microelement ML, and a second plate P2 provided on the first plate P1 and having an inner diameter smaller than the first through-hole h1 and a microelement support MS including a carrier substrate CP on which the microelement ML is temporarily fixed. The microelement carrier MT constituting the microelement transfer system 100 according to a preferred embodiment of the present disclosure may include the microelement carrier MT according to the preferred embodiment of the present disclosure, and a first modification example and second modified example may be provided.

The microelement carrier MT may include the first plate and second plate, P1 and P2. At least one of the first plate and seconds plates, P1 and P2, may be made of the anodic oxide film 10 material. Since the anodic oxide film 10 material has a low coefficient of thermal expansion, thermal deformation due to temperature in a high-temperature environment can be minimized. In performing the process of adsorbing the microelement ML, if the alignment for adsorption between the microelement carrier MT and the microelement ML temporarily fixed to the carrier substrate (CP) is misaligned, the microelement ML adsorption efficiency may be degraded. However, the microelement transfer system 100, according to a preferred embodiment of the present disclosure, includes a microelement carrier MT made of an anode oxide film 10 material, and when adsorbing the microelement ML using the microelement carrier MT, the position arrangement of the second through-hole h2 of the microelement carrier MT may not be deformed by high temperature. As a result, the problem of misalignment for adsorption between the microelement carrier MT and the microelement ML does not occur, thereby improving the adsorption efficiency of the microelement transfer system 100 according to a preferred embodiment of the present disclosure.

The microelement transfer system 100 according to a preferred embodiment of the present disclosure may relatively move at least one of the microelement carrier MT and the microelement support MS in at least one direction so that the microelement ML contacts the sidewall hw of the first through-hole h1 to detach the temporarily fixed state of the microelement ML. In this case, at least one direction in which at least one of the microelement carrier MT or the microelement support MS relatively moves may be at least one of the x and y directions. For example, the microelement carrier MT or the microelement support MS may move in one of the −x direction and the +x direction and may also move in both the +x direction and −x direction. In addition, the microelement carrier MT or the microelement support MS may move in one of the −y directions and the +y direction and may move in both the +y direction and −y direction. In addition, the microelement carrier MT or the microelement support MS may move in four directions in the +x direction, −x direction, +y direction, and −y direction.

For example, when the microelement carrier MT moves in at least one of the x and y directions, the microelement support MS may maintain a fixed state. The microelement carrier MT may move in at least one of the x and y directions in a state where the microelement ML is inserted into the first through-hole h1. The microelement ML temporarily fixed to the carrier substrate CP of the microelement support MS can be in contact with the side wall hw of the first through-hole h1 through the movement of the microelement carrier MT in at least one of the x and y directions. For example, when the microelement carrier MT moves in the x direction, the microelement ML may come into contact with the sidewall hw in the −x direction of the first through-hole h1. In addition, when the microelement carrier MT moves in the y direction, the microelement ML may come into contact with the sidewall hw in the −y direction of the first through-hole h1. The microelement ML contacts the side wall hw of the first through-hole h1 according to the movement of the microelement carrier MT in at least one of the x and y directions, and thus a temporarily fixed position on the carrier substrate CP may be moved. As the position of the microelement ML is moved, the temporarily fixed state may be primarily detached. The microelement carrier MT may be positioned in at least one of x and y directions to primarily detach the microelement ML on the carrier substrate CP and then can perform a process of adsorbing the microelement ML. Since the microelement ML on the carrier substrate CP is primarily detached by the microelement carrier MT, the microelement ML may be more efficiently collectively adsorbed in an adsorption process using the microelement carrier MT.

The microelement ML temporarily fixed on the carrier substrate CP may be detached from the carrier substrate CP in order to be transferred to the target substrate. At this time, UV light may be applied to lose the adhesiveness of the UV adhesive UV to the microelement ML from the lower portion of the carrier substrate CP. However, even if the adhesive strength of the UV adhesive UV is lost to some extent through UV light irradiation, since the size of the microelement ML is minute and the second through-hole h2 in which the vacuum suction force for adsorbing the microelement ML is formed to be smaller than the size of the microelement ML, it may be difficult to detach the microelement ML from UV adhesive UV at once.

However, in the microelement transfer system 100 according to a preferred embodiment of the present disclosure, after inserting the microelement ML into the first through-hole h1 of the microelement carrier MT, the microelement carrier MT may be moved in at least one of the x and y directions. As a result, the position of the microelement ML may be moved in a temporarily fixed state while contacting the side wall hw of the first through-hole h1. Through this, primary detachment of the microelement ML in a temporarily fixed state on the carrier substrate CP may be performed. In the primary detachment process, the UV adhesive UV may be in a state in which adhesiveness is lost caused by UV light irradiation.

In other words, before moving the position of the microelement ML by using the microelement carrier MT, a process of radiating UV light to the UV adhesive UV to lose adhesiveness may be first performed. The microelement ML may be detached by moving in position by the microelement carrier MT on the UV adhesive UV in which UV light is applied, and adhesive force to the microelement ML is lost.

In contrast, a process of irradiating UV light to the UV adhesive UV to lose adhesive force may be simultaneously performed with a process of uniformly attaching and detaching the microelement ML by moving the microelement carrier MT. Specifically, after inserting the microelement ML into the first through-hole h1 of the microelement carrier MT, a process of irradiating UV light to the UV adhesive UV may be performed before moving the microelement carrier MT in at least one of the x and y directions. Accordingly, the process of losing the adhesion of the UV adhesive UV and the process of primarily attaching and detaching the microelement ML using the microelement carrier MT may be simultaneously performed.

The microelement transfer system 100, according to a preferred embodiment of the present disclosure, moves the microelement ML in a position through the microelement carrier MT by a predetermined distance, primarily detaches the microelement ML, and then adsorbs the microelement ML so that collective adsorption and detachment of the microelement ML can be more effectively performed. The microelement ML may be adsorbed to the second through-hole h2 by the vacuum suction force of the microelement carrier MT and detached from the UV adhesive UV at the same time. Therefore, in the microelement transfer system 100, according to a preferred embodiment of the present disclosure, collective adsorption and detachment of the microelement ML can be effectively implemented.

In contrast, when the microelement support MS moves in at least one of the x and y directions, the microelement carrier MT may maintain a fixed state. At this time, the microelement ML may be inserted into the first through-hole h1 of the microelement carrier MT.

The microelement support MS may include a glass substrate G and a carrier substrate CP including a UV adhesive UV provided on the glass substrate G and temporarily fixed to the microelement ML. An adsorption member 5 made of a ceramic material that vacuum adsorbs the carrier substrate CP under the carrier substrate CP may be provided under the carrier substrate CP. In other words, the microelement support MS may include a carrier substrate CP including a glass substrate G and UV adhesive UV, and an adsorption member 5 provided under the carrier substrate CP.

The adsorption member 5 may be provided with a plurality of holes 5a passing through the adsorption member 5 in the thickness direction. The adsorption member 5 may be connected to a vacuum port that supplies or releases air pressure. Air pressure may be transferred to the hole 5a of the adsorption member 5 according to the operation of the vacuum port. The adsorption member 5 may have a vacuum suction force formed by the air pressure supplied to the hole 5a. The adsorption member 5 may maintain an adsorption state of the carrier substrate CP through a vacuum suction force.

Since the adsorption member 5 is made of a ceramic material, the adsorption member may have a low coefficient of thermal expansion. Accordingly, thermal deformation due to temperature may be minimized in a high-temperature environment. The adsorption member 5 may have a configuration supporting the carrier substrate CP on which the microelement ML is temporarily fixed. Therefore, when the adsorption member 5 is thermally deformed by temperature in a high-temperature environment, the position of the carrier substrate CP may be modified, and furthermore, the position arrangement of the microelement ML on the carrier substrate CP may be modified. When the adsorption member 5 is vulnerable to thermal deformation due to temperature in a high-temperature environment, the alignment between the microelement carrier MT and the microelement ML is misaligned when the microelement ML for the microelement carrier MT is adsorbed, resulting in a problem that the adsorption efficiency is degraded.

However, in the microelement transfer system 100, according to a preferred embodiment of the present disclosure, it is possible to prevent thermal deformation easily even when exposed to a high-temperature environment by forming the adsorption member 5 supporting the carrier substrate CP made of a ceramic material having a low thermal expansion coefficient. Accordingly, an efficient microelement adsorption process may be performed without misalignment between the microelement carrier MT and the microelement support MS.

The microelement support MS may be provided to be movable in x and y directions. In this case, the entire microelement support MS may move in the x and y directions by the movement of the adsorption member in the x and y directions. In the microelement transfer system 100, according to a preferred embodiment of the present disclosure, the microelement ML may be primarily detached by moving the position of the microelement ML in a temporarily fixed state by a predetermined distance according to the movement of at least one of the x and y directions of the microelement support MS.

As described above, the microelement transfer system 100, according to a preferred embodiment of the present disclosure, primarily detaches the microelement ML having lost adhesion to the UV adhesive UV due to UV light irradiation while moving in position, thereby implementing more effective adsorption and detachment of the microelement ML.

A method of manufacturing an electronic product in which microelement ML is mounted according to a preferred embodiment of the present disclosure may be performed using a microelement transfer system according to a preferred embodiment of the present disclosure.

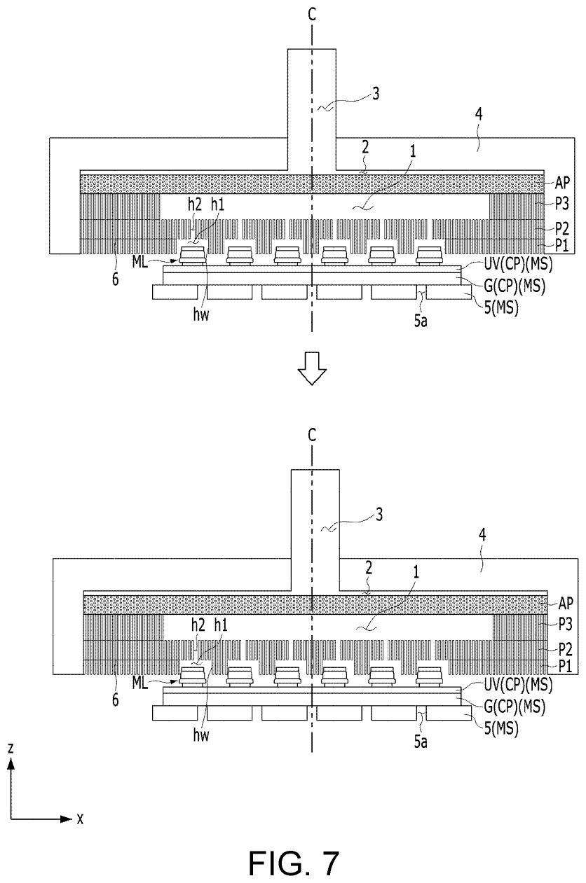

FIGS. 7 to 9 are schematic diagrams showing sequential processes according to a method of manufacturing an electronic product on which a microelement ML is mounted according to a preferred embodiment of the present disclosure. FIGS. 7 to 9 show that a method of manufacturing an electronic product on which a microelement ML is mounted according to a preferred embodiment of the present disclosure is performed by using a microelement carrier MT according to a preferred embodiment of the present disclosure. However, the microelement carrier MT may be provided as a first modified example and a second modified example.

The method of manufacturing an electronic product in which microelement ML is mounted according to a preferred embodiment of the present disclosure includes: moving the microelement carrier MT toward the carrier substrate CP to insert the microelement ML into the first through-hole h1 of the microelement carrier MT; detaching the microelement ML from a temporarily fixed state by contacting the side wall of the first through-hole h1 by relatively moving at least one of the microelement support MS including the microelement carrier MT or the carrier substrate CP in at least one direction; and adsorbing the microelements ML with the vacuum suction force of the microelement carrier MT.

The method of manufacturing an electronic product in which a microelement ML is mounted according to a preferred embodiment of the present disclosure includes detaching the microelement ML from a temporarily fixed state by relatively moving at least one of the microelement transporter and the microelement support MS in at least one direction, thereby more efficiently performing a process of adsorbing the microelement ML on the carrier substrate CP and transferring the microelement ML to the target substrate.

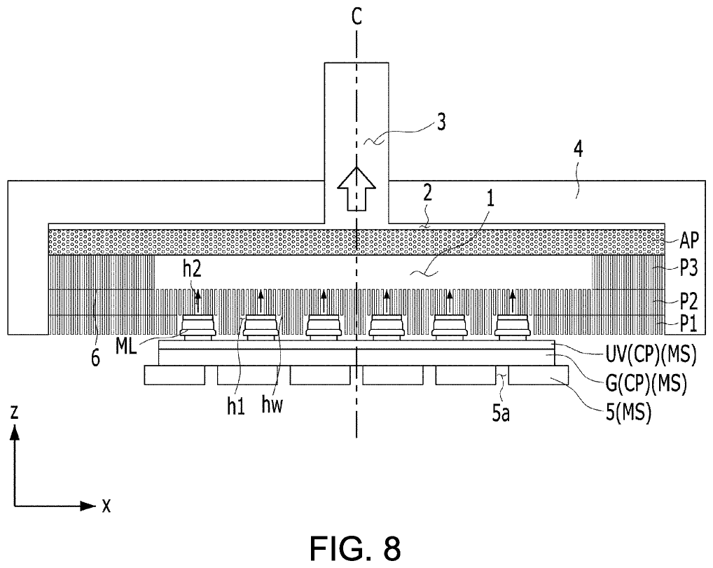

First, a method of manufacturing an electronic product on which a microelement ML is mounted according to a preferred embodiment of this disclosure will be described in detail with reference to FIGS. 7 and 8 when the microelement carrier MT is moved in at least one of the x and y directions.

FIGS. 7 and 8 are schematic diagrams showing a sequential process according to a method of manufacturing an electronic product on which a microelement ML, according to a preferred embodiment of this disclosure, is mounted when the microelement carrier MT is moved in at least one of x and y directions and the microelement support MS is maintained in a fixed state.

As shown in FIG. 7, first, a process of moving the microelement carrier MT to the carrier substrate CP side of the microelement support MS may be performed. The alignment between the first through-hole h1 and the microelement ML may be aligned in order to insert the microelement ML into the first through-hole h1 before descending toward the carrier substrate CP. Then, the microelement carrier MT descends to insert the microelement ML into the first through-hole h1. When the microelement carrier MT for inserting the microelement ML into the first through-hole h1 is descended, the microelement carrier MT may be descended to a height at which the microelement ML does not contact one surface of the second plate P2 exposed by the first through-hole h1. In other words, the microelement carrier MT descends to the extent that a certain distance between one surface of the second plate P2 and the microelement ML is maintained, and may insert the microelement ML into the first through-hole h1. This may be to maintain a distance for adsorbing the microelement ML with a vacuum suction force when air pressure is supplied to the second through-hole h2.

Then, a process of moving the microelement carrier MT in at least one of the x and y directions may be performed. As an example, the microelement carrier MT may move in the x direction. As shown in FIG. 7, the microelement carrier MT may move in the x direction from the central axis C of the microelement carrier MT. Accordingly, the microelement ML may come into contact with the sidewall hw in the −x direction inside the first through-hole h1. The microelement ML in contact with the side wall hw in the −x direction of the first through-hole h1 may be primarily detached while moving in the +x direction on the carrier substrate CP according to the movement of the microelement carrier MT in the +x direction.

Next, before adsorbing the microelement ML, aligning the microelement ML with the second through-holes h2 of the microelement carrier MT may be performed. The microelement carrier MT contacts the side wall of the first through-hole h1 with the microelement ML through the position movement of the microelement carrier MT to primarily detach the microelement ML, and then, a process of adsorbing the microelement ML may be performed at that position. However, in method of the manufacturing an electronic product on which the microelement ML is mounted according to a preferred embodiment of the present disclosure, after primarily detaching the microelement ML by using the microelement carrier MT, aligning the alignment of the second through-hole h2 of the microelement carrier MT and the microelement ML may be performed. Through this, the microelement carrier MT may adsorb the microelement ML in a state where the second through-hole h2 is positioned at the center of the upper surface of the microelement ML. By aligning the alignment of the second through-hole h2 and the microelement ML, at least a portion of the lower opening of the second through-hole h2 deviates from the upper surface of the microelement ML. Therefore, it is possible to prevent a problem in which the microelement ML is not properly adsorbed due to leakage of the vacuum suction force.

Then, as shown in FIG. 8, air pressure may be supplied to the second through-hole h2 of the microelement carrier MT to form a vacuum suction force. The microelement ML accommodated in the first through-hole h1 may be adsorbed to the microelement carrier MT by the vacuum suction force formed in the second through-hole h2. At this time, the UV adhesive UV is in a state in which adhesiveness is lost by UV light irradiation, and the microelement ML may be in a primarily detached state while being moved by the microelement carrier MT in a temporarily fixed state of the carrier substrate CP. Accordingly, the microelement ML on the carrier substrate CP can be more easily detached and adsorbed to the microelement carrier MT by the vacuum suction force of the microelement carrier MT.

The microelement ML on the carrier substrate CP is primarily detached according to the movement of the microelement carrier MT, and at the same time, the microelement ML on the carrier substrate CP can be detached due to loss of adhesiveness by UV light applied to the UV adhesive UV. In other words, the microelement ML is detached from the UV adhesive UV by the microelement carrier MT in the upper direction of the microelement ML, and at the same time, a process of being detached from the UV adhesive UV may be performed in the lower direction of the microelement ML by irradiating the UV adhesive UV with UV light. Due to this, compared to detaching the microelement ML only by the process of losing the adhesion of the UV adhesive UV, the entire microelement ML may be effectively detached without the microelement ML that is not detached from the carrier substrate CP. As a result, collective adsorption of microelements ML using the microelement carrier MT is efficiently performed without microelements ML that are not properly detached from the UV adhesive UV and are not adsorbed to the microelement carrier MT.

The microelement ML collectively adsorbed on the microelement carrier MT by detaching the temporarily fixed state of the microelement ML temporarily fixed on the carrier substrate CP may be transferred to the target substrate.

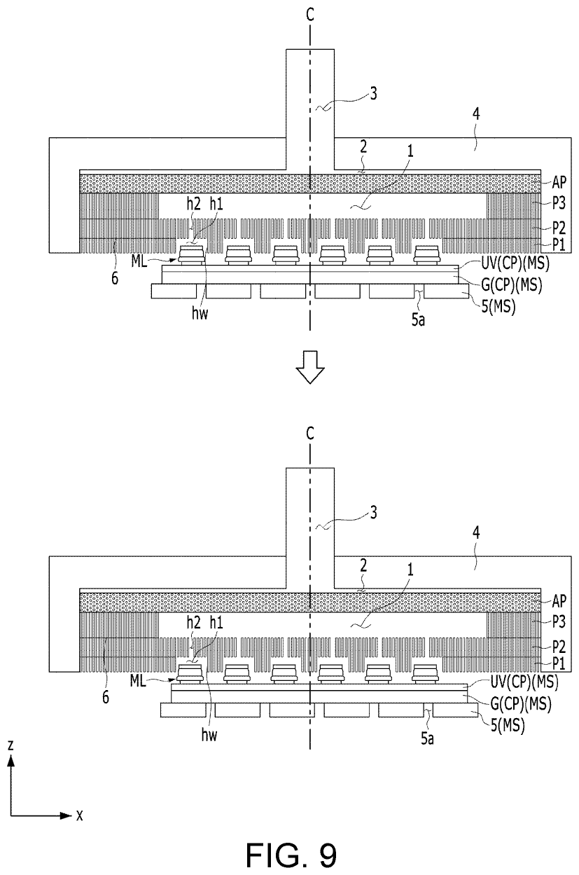

FIG. 9 are schematic diagrams showing a sequential process according to a method of manufacturing an electronic product on which a microelement ML, according to a preferred embodiment of this disclosure, is mounted when the microelement support MS is moved in at least one of x and y directions and the microelement carrier MT is maintained in a fixed state. In this case, in the method of manufacturing the electronic product in which the microelement ML is mounted according to a preferred embodiment of the present disclosure, the microelement carrier MT is fixed, and all steps may be performed in the same process except that the microelement support MS moves in at least one direction.

As shown in FIG. 9, a process of descending the microelement carrier MT toward the carrier substrate CP on which the microelements ML are temporarily fixed may be performed. The alignment between the first through-hole h1 and the microelement ML may be aligned in order to insert the microelement ML into the first through-hole h1 before descending toward the carrier substrate CP. Then, the microelement ML may be inserted into the first through-hole h1 by descending toward the carrier substrate CP.

Then, a process of moving the microelement support MS in at least one of the x and y directions may be performed. As an example, the microelement support MS may move in the x direction. As shown in FIG. 9, the microelement support MS may move in the x direction from the central axis C of the microelement support MS. Accordingly, the microelement ML may be moved toward the side wall hw in the −x direction by contacting the side wall hw in the x direction inside the first through-hole h1 of the microelement carrier MT. The microelement ML is moved on the carrier substrate CP by the position movement of the microelement support MS and can be primarily detached. At this time, the UV adhesive UV to which the microelement ML is directly adhered may be in a state in which UV light is applied to lose the adhesive force. The microelement ML on the carrier substrate CP may be detached while being moved in position according to the movement of the microelement support MS, and at the same time, the microelement ML on the carrier substrate CP can be detached due to loss of adhesiveness by UV light applied to the UV adhesive UV For this reason, compared to the process of detaching the microelements ML only by the process of losing the adhesiveness of the UV adhesive UV to the microelement ML, the entire microelement ML on the carrier substrate CP may be effectively detached without the microelement ML that is not detached from the UV adhesive UV.

The microelement carrier MT may be moved on the carrier substrate CP to align the adsorption alignment of the detached microelement ML and then adsorb the microelement ML.

Then, the microelement carrier MT may transfer the adsorbed microelement ML to a target substrate and transfer the microelement ML to the target substrate.

The method of manufacturing an electronic product in which microelement ML is mounted according to a preferred embodiment of the present disclosure may include the process of detaching the microelement ML temporarily fixed on the carrier substrate CP by performing physical contact using the microelement carrier MT or the microelement support MS. Accordingly, the microelement ML temporarily fixed on the carrier substrate CP can be collectively detached from the carrier substrate CP without a problem of non-detachment. As a result, by being non-detached on the carrier substrate CP, the entire microelement ML is collectively adsorbed to the microelement carrier MT without the microelement ML to which the microelement carrier MT is not adsorbed and transferred on the target substrate, thereby improving the transfer efficiency of the microelement ML on the target substrate.

Hereinabove, although preferred embodiments of the present disclosure have been described, those ordinarily skilled in the art may change and modify the present disclosure without departing from the scope and spirit of the claimed disclosure.

### DESCRIPTION OF REFERENCE NUMERALS

MT: microelement carrier
P1: first plate P2: second plate
h1: first through-hole h2: second through-hole
hw: sidewall
MS: microelement support
100: microelement transfer system

1. (canceled)

2. (canceled)

3. (canceled)

4. (canceled)

5. A microelement transfer system comprising:
a microelement carrier comprising:
a first plate having a plurality of first through-holes corresponding to respective microelements;
a second plate provided on the first plate and having a second through-hole having a smaller inner diameter than that of the first through-hole, wherein at least one of the first plate and the second plate is made of an anodic oxide film material; and
a microelement support comprising a carrier substrate on which the microelements are temporarily fixed,
wherein the microelement transfer system relatively moves at least one of the microelement carrier and the microelement support in at least one direction so that each of the microelements comes into contact with a side wall of a corresponding one of the first through-holes and detaches to be released from the temporarily fixed state.

6. The microelement transfer system of claim 5, wherein the carrier substrate comprises a glass substrate and a UV adhesive provided on the glass substrate and temporarily fixing the microelements thereon.

7. The microelement transfer system of claim 5, wherein the microelement support comprises a ceramic adsorption member configured to adsorb the carrier substrate from below the carrier substrate by vacuum absorption.

8. The microelement transfer system of claim 5, wherein the at least one direction in which the relative movement is performed is at least one of an x direction and a y direction.

9. (canceled)

10. (canceled)
